(19) United States
(12) Patent Application Publication
(10) Pub. No.: US 2025/0221238 A1
(43) Pub. Date: Jul. 3, 2025

(54) DISPLAY APPARATUS

(71) Applicant: LG Display Co., Ltd., Seoul (KR)

(72) Inventors: Byung June MUN, Paju-si (KR); Jung Seop YOON, Paju-si (KR)

(21) Appl. No.: 18/658,718

(22) Filed: May 8, 2024

(30) Foreign Application Priority Data
Dec. 29, 2023 (KR) 10-2023-0197475

(51) Int. Cl. H10K 59/80; H10K 59/124; H10K 59/35

(52) U.S. Cl. CPC H10K 59/80515; H10K 59/124; H10K 59/80518; H10K 59/878; H10K 59/352

(57) ABSTRACT

Embodiments of the present disclosure relates to a display device including a substrate on which a plurality of subpixels are disposed. Each of the plurality of subpixels includes a first light emitting area and a second light emitting area adjacent to the first light emitting area. The display device includes a first planarization layer on the substrate, and a second planarization layer which is disposed on the first planarization layer. The second planarization layer includes a first portion having a convex upper surface in a direction perpendicular to the first planarization layer in an area overlapping the first light emitting area. Embodiments of the present disclosure may increase light extraction efficiency of a display device.

### CROSS REFERENCE TO RELATED APPLICATION

This application claims priority from Korean Patent Application No. 10-2023-0197475, filed on Dec. 29, 2023, which is hereby incorporated by reference for all purposes as if fully set forth herein.

### BACKGROUND

### Technical Field

The present disclosure relates to a display device, more particularly, relates to a display device capable of increasing light extraction efficiency.

### Description of the Related Art

A light emitting display device (OLED) is a self-emitting display device, and unlike a liquid crystal display device (LCD), the light emitting display does not require a separate light source and can be manufactured in a lightweight and thin form. In addition, light emitting display devices are not only advantageous in terms of power consumption due to low voltage operation, but also have excellent color reproduction, response speed, viewing angle, and contrast ratio (CR), and are being studied as next-generation display devices.

Since a part of the light emitted in a light emitting display device may be trapped inside the light emitting display device, there may decrease light extraction efficiency.

In order to increase the light extraction efficiency of a light emitting display device, the light traveling inside the light emitting display device among the light emitted from a light emitting layer is required to be extracted to the outside. In order to extract light traveling inside the light emitting display device to the outside, there may be used a structure in which reflective electrodes are arranged so that light traveling inside the light emitting display device faces the outside.

### BRIEF SUMMARY

However, the size of an area where light is emitted in a light emitting display device may vary depending on the type of display device. In addition, if the size of a light emitting area is large, the reflective electrodes may have limitations in extracting light traveling from the light emitting area to the inside of the display device to the outside, and there may have imitations in increasing luminance within a viewing angle. Accordingly, the inventors of the present disclosure have invented a display device capable of maximizing light extraction efficiency and increasing luminance within a viewing angle.

Embodiments of the present disclosure may provide a display device capable of maximizing light extraction efficiency and a method of manufacturing the same.

Embodiments of the present disclosure may provide a display device capable of increasing luminance within a viewing angle and a method of manufacturing the same.

The problems to be solved according to an embodiment of the present disclosure are not limited to the problems as above, and another problems may be clearly understood by those skilled in the art from the description below.

According to an embodiment of the present disclosure, there may be provided a display device capable of maximizing light extraction efficiency. There is formed a substrate on which a plurality of subpixels are arranged. The plurality of subpixels includes a first light emitting area and a second light emitting area surrounding the first light-emitting area. A first planarization layer may be formed on the substrate. There may be formed a second planarization layer which is disposed on the first planarization layer, and includes a first portion having a convex upper surface in a direction perpendicular to the first planarization layer in an area overlapping the first light emitting area and a second portion disposed around the first portion.

According to an embodiment of the present disclosure, there may be provided a display device capable of maximizing light extraction efficiency. There is formed a substrate on which a plurality of subpixels are disposed, each of the plurality of subpixels including a light emitting area. A first planarization layer may be formed on the substrate. There may be formed a second planarization layer which is disposed on the first planarization layer, and comprises at least a part of a convex portion located in an area overlapping at least a part of the light emitting area and having a convex upper surface in a direction perpendicular to the first planarization layer.

A display device according to embodiments of the present disclosure may have an effect of increasing light extraction efficiency.

In addition, there may have an effect of increasing the luminance within a viewing angle of a display device.

In addition, according to the embodiments of the present disclosure, there may provide a display device capable of low power consumption by increasing light extraction efficiency.

The effects of the present disclosure are not limited to the effects described above, and other effects not described will be clearly understood by those skilled in the art from the description below.

### BRIEF DESCRIPTION OF THE SEVERAL VIEWS OF THE DRAWINGS

FIG. 1 illustrates an example of the structure of a display device and a circuit structure included in a subpixel according to embodiments of the present disclosure.

FIG. 2 illustrates an example of a cross-sectional structure of a display device according to embodiments of the present disclosure.

FIGS. 3A and 3B are enlarged views of part A of FIG. 2 and are views for explaining optical characteristics of the display device shown in FIG. 2.

FIG. 4 illustrates an example of a planar structure of a display device according to embodiments of the present disclosure.

FIG. 5 illustrates an example of the cross-sectional structure of II′ in FIG. 4.

FIG. 6 is an enlarged view of part B of FIG. 5.

FIGS. 7A and 7B are diagrams for explaining optical characteristics of the display device shown in FIG. 6.

FIGS. 8 to 10 illustrate other examples of part B of FIG. 5.

FIGS. 11A to 11C are diagrams for explaining a method of manufacturing a display device according to embodiments of the present disclosure.

FIG. 12 illustrates an example of a light emitting device structure of a display device according to an embodiment of the present disclosure.

### DETAILED DESCRIPTION

The advantages and features of the present disclosure and methods of the realization thereof will be apparent with reference to the accompanying drawings and detailed descriptions of embodiments. The present disclosure should not be construed as being limited to the embodiments set forth hereinafter and may be embodied in a variety of different forms. Rather, these embodiments are provided so that the present disclosure will be thorough and complete, and will fully convey the scope of the present disclosure to those having ordinary knowledge in the technical field.

The shapes, sizes, dimensions (e.g., length, width, height, thickness, radius, diameter, area, etc.), ratios, angles, numbers, number of elements, and the like, inscribed in the drawings to illustrate embodiments are illustrative only, and the present disclosure is not limited to the embodiments illustrated in the drawings.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Throughout this document, the same reference numerals and symbols will be used to designate the same or like components. In the following description of the present disclosure, detailed descriptions of known functions and components incorporated into the present disclosure will be omitted when it is determined that the description may make the subject matter in some embodiments of the present disclosure rather unclear. It will be understood that the terms “comprise”, “include”, “have”, and any variations thereof used herein are intended to cover non-exclusive inclusions unless explicitly stated to the contrary. Descriptions of components in the singular form used herein are intended to include descriptions of components in the plural form, unless explicitly stated to the contrary.

In the analysis of a component, it shall be understood that an error range is included therein, even in the situation in which there is no explicit description thereof.

When spatially relative terms, such as “on”, “above”, “under”, “below”, and “on a side of”, are used herein for descriptions of relationships between one element or component and another element or component, one or more intervening elements or components may be present between the one and other elements or components, unless a term, such as “immediately” or “directly”, is used.

In addition, terms, such as “first” and “second” may be used herein to describe a variety of components. It should be understood, however, that these components are not limited by these terms. These terms are merely used to discriminate one element or component from other elements or components. Thus, a first component referred to as first hereinafter may be a second component within the spirit of the present disclosure.

The features of example embodiments of the present disclosure may be partially or entirely coupled or combined with each other and may work in concert with each other or may operate in a variety of technical methods. In addition, respective example embodiments may be carried out independently or may be associated with and carried out in concert with other embodiments.

Hereinafter, a variety of embodiments will be described in detail with reference to the accompanying drawings.

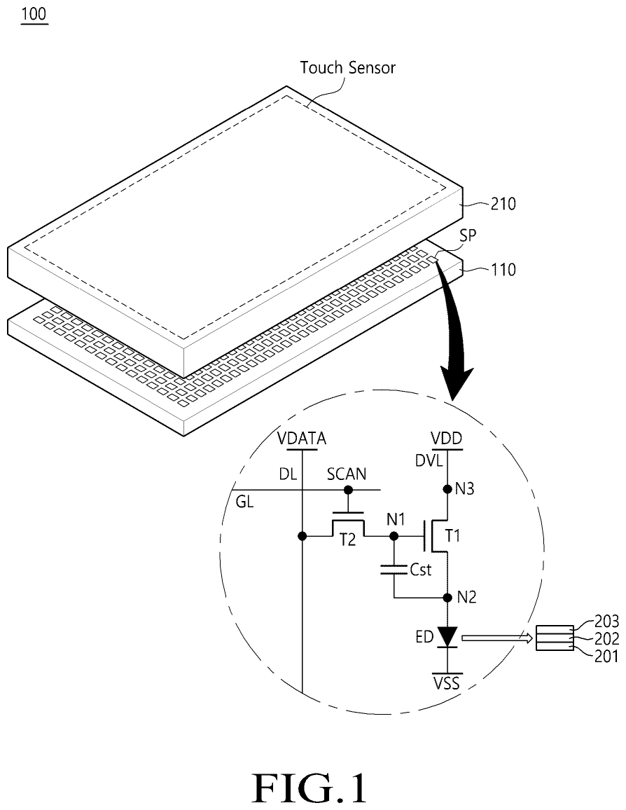

FIG. 1 illustrates an example of the structure of a display device and a circuit structure included in a subpixel according to embodiments of the present disclosure.

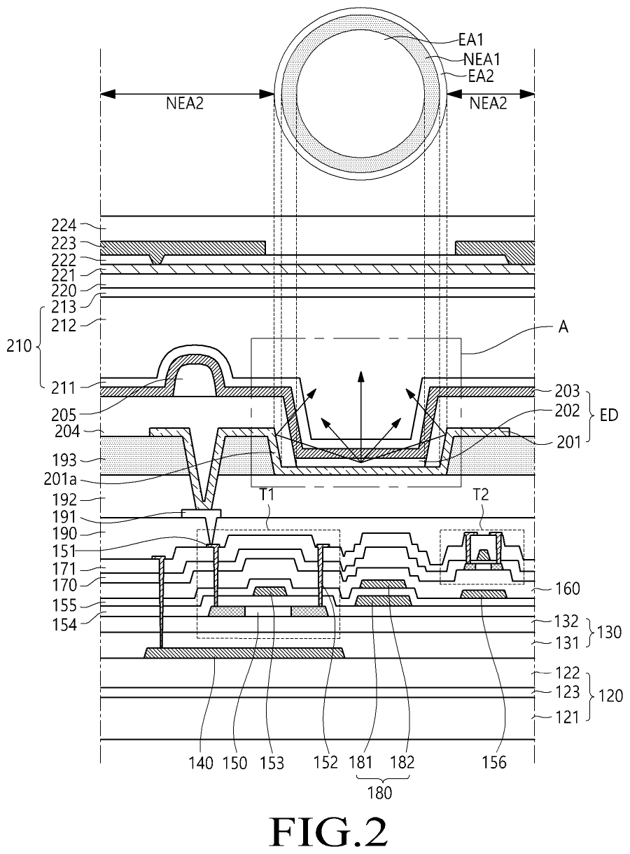

FIG. 2 illustrates an example of a cross-sectional structure of a display device according to embodiments of the present disclosure.

Referring to FIG. 1, a plurality of subpixels SP may be disposed in a display area of a display panel 110 included in a display device 100.

Each of the plurality of subpixels SP may include a light emitting element ED and a subpixel circuit unit configured to drive the light emitting element ED.

The subpixel circuit unit may include a driving transistor T1 for driving the light emitting element ED, a scan transistor T2 for transferring the data voltage VDATA to a first node N1 of the driving transistor T1, and a storage capacitor 180 for maintaining a constant voltage during one frame.

The driving transistor T1 may include a first node N1 to which a data voltage is applied, a second node N2 electrically connected to the light emitting element ED, and a third node N3 to which the driving voltage VDD is applied from a driving voltage line DVL. In the driving transistor T1, the first node N1 may be a gate node, the second node N2 may be a source node or a drain node, and the third node N3 may be a drain node or a source node. Hereinafter, for convenience of explanation, there illustrates a case in which the first node N1 is a gate node, the second node N2 is a source node, and the third node N3 is a drain node in the driving transistor T1, as an example.

The light emitting element ED may include a first electrode 201, a light emitting layer 202, and a second electrode 203. The first electrode 201 may be a pixel electrode disposed in each subpixel SP and may be electrically connected to the second node N2 of the driving transistor T1 of each subpixel SP. The second electrode 203 may be a common electrode commonly disposed in the plurality of subpixels SP, and a base voltage (VSS) may be applied thereto.

Alternatively, the first electrode 201 may be a common electrode, and the second electrode 203 may be a pixel electrode. Hereinafter, for convenience of explanation, it is assumed that the first electrode 201 is a pixel electrode and the second electrode 203 is a common electrode.

The light emitting element ED may have a specific light emitting area, and the number of light emitting areas may be one or more, as will be described later.

The light emitting element ED may be an organic light emitting diode (OLED), an inorganic light emitting diode, or a quantum dot light emitting device. In the case that the light emitting element ED is an organic light emitting diode, the light emitting layer 202 in the light emitting element ED may include an organic light emitting layer containing an organic material. For example, the light emitting layer 202 may have a tandem structure having two or more stacked units, but embodiments of the present disclosure are not limited thereto.

The scan transistor T2 may be controlled on-off by a scan signal SCAN, which is a gate signal applied through a gate line GL, and the scan transistor T2 may be electrically connected between the first node N1 of the driving transistor T1 and the data line DL.

The storage capacitor 180 may be electrically connected between the first node N1 and the second node N2 of the driving transistor T1.

The subpixel circuit unit may have a 2T1C structure including two transistors DT and ST and one capacitor Cst, and in some cases, may further include one or more transistors. Alternatively, the subpixel circuit unit may further include one or more capacitors.

The storage capacitor 180 may be an external capacitor intentionally designed outside the driving transistor T1 rather than a parasitic capacitor (e.g., Cgs, Cgd) which is an internal capacitor existing between the first node N1 and the second node (N2) of the driving transistor T1. Each of the driving transistor T1 and the scan transistor T2 may be an n-type transistor or a p-type transistor.

Circuit elements within each subpixel, in particular, light emitting devices EDs implemented with organic light-emitting diodes OLEDs containing organic materials may be vulnerable to external moisture or oxygen. Accordingly, an encapsulation layer 210 may be disposed on the display panel 110 to prevent oxygen from penetrating into the circuit elements (particularly, the light emitting devices ED). The encapsulation layer 210 may be disposed to cover the light emitting element ED.

A touch sensor layer to provide a touch function may be disposed on the encapsulation layer 210. A touch sensor layer may include one or more layers, and may include a touch electrode for detecting a touch, a touch driving circuit for driving the touch electrode.

Referring to FIG. 2, the display device 100 may include a substrate 120.

The substrate 120 may include a first substrate 121 and a second substrate 122, and may include an intermediate film 123 between the first substrate 121 and the second substrate 122. Here, for example, the intermediate film 123 may be an inorganic film and may block moisture penetration.

A first buffer layer 130 may be disposed on the substrate 120.

The first buffer layer 130 may be a single layer or multiple layers. In the case that the first buffer layer 130 is a multiple layer, the first buffer layer 130 may include a multi-buffer layer 131 and an active buffer layer 132.

A first light blocking layer 140 may be disposed between the first buffer layer 130 and the substrate 120. The first light blocking layer 140 may overlap all or part of a first active layer 150.

The first light blocking layer 140 may function as a light shield which blocks light incident from the bottom.

There may be formed various transistors T1 and T2, storage capacitor 180, and various electrodes or signal lines on the first buffer layer 130.

A first transistor T1 may be disposed on the first buffer layer 130. The first transistor T1 may include a first active layer 150, a first source electrode 151, a first drain electrode 152, and a first gate electrode 153.

A first gate insulating layer 154 may be disposed on the first active layer 150 of the first transistor T1.

Here, the first active layer 150 of the first transistor T1 may include a first channel area overlapping the first gate electrode 153, a first source connection area located on one side of the first channel area, and a first drain connection area located on the other side of the first channel area.

A first interlayer insulating layer 155 may be disposed on the first gate insulating layer 154.

A second buffer layer 160 and a second gate insulating layer 170 may be disposed on the first interlayer insulating layer 155. A second light blocking layer 156 may be disposed between the first interlayer insulating layer 155 and the second buffer layer 160. The second light blocking layer 156 may play the same role as the first light blocking layer 140.

A second transistor T2 may be disposed on the second buffer layer 160. The second transistor T2 may be a transistor for transmitting various signals or voltages to various electrodes inside the display panel.

A second interlayer insulating layer 171 may be disposed on the second transistor T2.

The first source electrode 151 and the first drain electrode 152 of the first transistor T1 may be disposed on the second interlayer insulating layer 171.

The first source electrode 151 and the first drain electrode 152 of the first transistor T1 may be connected to the first source connection area and the first drain connection area of the first active layer 150, respectively via the through holes of the second interlayer insulating layer 171, the second gate insulating layer 170, the second buffer layer 160, the first interlayer insulating layer 155 and the first gate insulating layer 154.

Referring to FIG. 2, the storage capacitor 180 may include a first capacitor electrode 181 and a second capacitor electrode 182. The first interlayer insulating layer 155 may be disposed between the first capacitor electrode 181 and the second capacitor electrode 182.

A third interlayer insulating layer 190 may be disposed on the first transistor T1. For example, the third interlayer insulating layer 190 may be disposed on the first source electrode 151 and the first drain electrode 152 of the first transistor T1.

A connection electrode 191 may be disposed on the third interlayer insulating layer 190.

The connection electrode 191 may be an electrode which relays the electrical connection between the first source electrode 151 of the first transistor T1 and a first electrode 201 of the light emitting element ED.

The connection electrode 191 may be electrically connected to the first source electrode 151 of the first transistor T1 through a hole in the third interlayer insulating layer 190.

A first planarization layer 192 may be disposed on the connection electrode 191 and the third interlayer insulating layer 190.

A second planarization layer 193 may be disposed on the first planarization layer 192. The first electrode 201 of the light emitting element ED may be electrically connected to the connection electrode 191 through a contact hole area of the first planarization layer 192 and the second planarization layer 193. In some embodiments, the first planarization layer 192 and the second planarization layer 193 are separate and distinct from each other. To be specific, the first planarization layer 192 may be deposited first and then the second planarization layer 193 may be deposited on top of the first planarization layer 192 at a later process. However, in some embodiments, the first and second planarization layer 192, 193 can be formed as a single planarization layer.

FIG. 2 illustrates a structure in which the first planarization layer 192 is disposed on the third interlayer insulating layer 190 and the second planarization layer 193 is disposed on the first planarization layer 192. The embodiments of this disclosure are not limited thereto. For example, the second planarization layer 193 may be disposed directly on the third interlayer insulating layer 190.

The second planarization layer 193 may include at least one opening area.

The first electrode 201 of the light emitting element ED may be disposed on the first planarization layer 192 and the second planarization layer 193.

The first electrode 201 may include a reflective layer and a transparent conductive layer. For example, a transparent conductive layer may be disposed on the reflective layer. The first electrode 201 is a layer for supplying holes to the light emitting layer 202, and may include an opaque conductive material with a high work function. For example, the reflective layer of the first electrode 201 is made of highly reflective metal materials such as silver (Ag), aluminum (Al), gold (Au), palladium (Pd), copper (Cu), tungsten (W), and molybdenum (Mo), chromium (Cr), tantalum (Ta), and titanium (Ti) or alloys thereof, but is not limited thereto. The transparent conductive layer of the first electrode 201 may be made of, for example, indium-tin-oxide (ITO), which is a transparent conductive oxide (TCO), but is not limited thereto.

The first electrode 201 may be disposed within an opening area of the second planarization layer 193. Specifically, the first electrode 201 may be disposed on the bottom and side of the opening area provided in the second planarization layer 193, and may be disposed to extend to a portion of the upper surface of the second planarization layer 193.

A portion of the first electrode 201 disposed on the side of the second planarization layer 193 may be defined as an inclined portion 201a of the first electrode 201. The inclined portions 201a of the first electrode 201 may be disposed on both sides of the opening area of the second planarization layer 193.

As shown in FIG. 2, the first electrode 201 may be in contact with the upper surface of the first planarization layer 192 in an area corresponding to the opening area of the second planarization layer 193.

In addition, the first electrode 201 may be in contact with the connection electrode 191 disposed below the first planarization layer 192 through contact holes provided in the second planarization layer 193 and the first planarization layer 192.

A bank layer 204 may be disposed on the first electrode 201 and the second planarization layer 193.

The bank layer 204 may include a bank hole exposing a portion of the top surface of the first electrode 201. That is, the bank hole formed in the bank layer 204 may overlap a portion of the first electrode 201.

The bank layer 204 may also overlap a portion of the opening area of the second planarization layer 193. Specifically, the bank layer 204 may be disposed within the opening area of the second planarization layer 193 and may also be partially disposed on the first electrode 201. In some embodiments, the bank layer 204 may extend between the light emitting layer 202 and the second surface SS of the second portion 193b of the planarization layer 193.

The light emitting layer 202 may be disposed in a bank hole where a portion of the upper surface of the first electrode 201 is exposed. That is, the light emitting layer 202 may be disposed on the first electrode 201 which does not overlap the bank layer 204.

The light emitting layer 202 may be disposed within the opening area of the second planarization layer 193.

The second electrode 203 may be disposed on the light emitting layer 202 and the bank layer 204. The second electrode 203 may be made of a transparent conductive material.

At least one spacer 205 may exist between the second electrode 203 and the bank layer 204. At least one spacer 205 may be arranged to overlap the contact hole area. Since the contact hole area formed in the first planarization layer 192 and the second planarization layer 193 is filled with the bank layer 204 and the spacer 205 is formed on the upper part of the contact hole area, a height of the bank layer 204 in the contact hole area including the spacer 205 may be greater than a height of the bank layer 204 partially overlapping the opening area.

The spacer 205 may be formed of the same material as the bank layer 204, but is not limited thereto. The bank layer 204 and spacer 205 may be formed of a transparent insulating material.

An encapsulation layer 210 may be disposed on the second electrode 203.

The encapsulation layer 210 may include a first encapsulation layer 211, a second encapsulation layer 212 on the first encapsulation layer 211, and a third encapsulation layer 213 on the second encapsulation layer 212.

The first encapsulation layer 211 and the third encapsulation layer 213 may be made of at least one inorganic material selected from silicon nitride (SiNx), silicon oxide (SiOx), or aluminum oxide (AlyOz), but are not limited thereto. The first encapsulation layer 211 and the third encapsulation layer 213 may be formed using a vacuum deposition method such as chemical vapor deposition (CVD) or atomic layer deposition (ALD), but are not limited thereto.

The second encapsulation layer 212 may cover foreign substances or particles which may occur during the manufacturing process. Additionally, the second encapsulation layer 212 may planarize a surface of the first encapsulation layer 211.

Layers for a touch function may be disposed on the encapsulation layer 210.

The layer for providing the touch function may include a touch buffer layer 220, a touch connection electrode 221, a touch interlayer insulating layer 222, a touch electrode 223, and a touch planarization layer 224.

For example, the touch buffer layer 220 may be disposed on the third encapsulation layer 213. The touch buffer layer 220 may block external moisture from penetrating into the light emitting element ED containing organic materials.

The touch connection electrode 221 may be disposed on the touch buffer layer 220. The touch connection electrode 221 may electrically connect a plurality of adjacent touch electrodes 223 arranged to be spaced apart.

The touch interlayer insulating layer 222 may be disposed on the touch connection electrode 221. The touch interlayer insulating layer 222 may include at least one opening area.

A touch electrode 223 may be disposed on the touch interlayer insulating layer 222. The touch electrode 223 may be disposed to fill the opening area of the touch interlayer insulating layer 222.

The touch electrode 223 may transmit a touch detection signal to a touch driving circuit or receive a touch driving signal from the touch driving circuit.

A touch planarization layer 224 may be disposed on the touch electrode 223. The touch planarization layer 224 may be disposed to cover the touch electrode 223 and may be formed of the same material as the second encapsulation layer 212, but is not limited thereto.

As shown in FIG. 2, light emitted from the light emitting element ED may travel in a direction perpendicular to the substrate 120 and be emitted to the outside of the display device 100.

In addition, a part of the emitted light may be reflected from the inclined portion 201a of the first electrode 201 and emitted to the outside of the display device 100. Therefore, light extraction efficiency may be partially increased.

However, even if the display device 100 includes the inclined portion 201a of the first electrode 201, since only a portion of the light emitted from the light emitting layer 202 may be reflected by the inclined portion 201a of the first electrode 201, there may be a limit to increasing the light extraction efficiency of the display device 100.

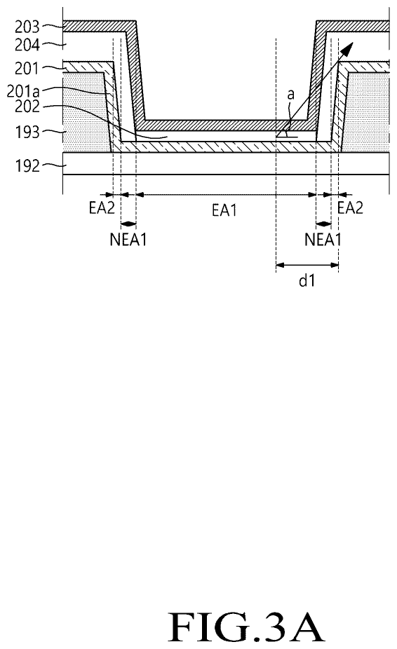

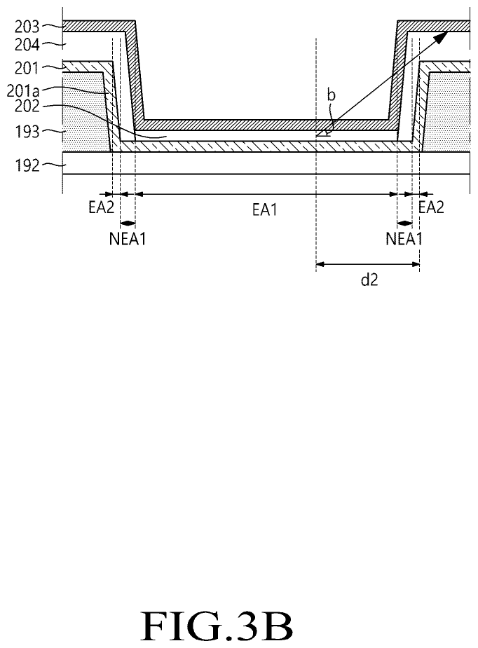

FIGS. 3A and 3B are enlarged views of part A of FIG. 2 and are views for explaining optical characteristics of the display device shown in FIG. 2.

Referring to FIGS. 3A and 3B, some of the light emitted from the light emitting layer 202 may be reflected from the inclined portion 201a of the first electrode 201.

For example, referring to FIG. 3A, among the light emitted from an arbitrary point of the light emitting layer 202, that is, a point d1 away from the outer boundary of a second light emitting area EA2, the light whose angle with the first planarization layer 192 is less than an ‘a’ degree may be reflected from the inclined portion 201a of the first electrode 201 and emitted to the outside of the display device 100.

However, as shown in FIG. 3A, among the light emitted from the point d1 away from the outer boundary of a second light emitting area EA2, the light having an angle of more than the ‘a’ degree with the first planarization layer 192 may be no longer reflected by the inclined portion 201a of the first electrode 201.

Light which is not reflected by the inclined portion 201a of the first electrode 201 may travel toward the inside of the display device 100. Light traveling toward the inside of the display device 100 may be totally reflected at an interface of the internal components of the display device 100 or may be reflected back by some components, and may be trapped inside the display device 100.

Among the light emitted from a point d1 away from the outer boundary of the second light emitting area EA2, light with an angle of more than ‘a’ degree with the first flattening layer 192 may be not emitted to the outside of the display device 100. Therefore, there may be a limit to increasing the light extraction efficiency of the display device 100.

In addition, referring to FIG. 3B, among the light emitted from the light emitting layer 202, the light with an angle of ‘b’ degrees with the first flattening layer 192 is no longer reflected by the inclined portion 201a of the first electrode 201 if the distance from the outer boundary of the second light emitting area EA2 is d2 or more.

Similarly, light which is not reflected by the inclined portion 201a of the first electrode 201 may travel toward the inside of the display device 100. The light traveling toward the inside of the display device 100 may be totally reflected at an interface of the internal components of the display device 100 or reflected back by some components, and may be trapped inside the display device 100.

That is, only light whose distance from the outer boundary of the second light emitting area EA2 is less than d2 may be emitted to the outside of the display device 100, which limits the increase in light extraction efficiency of the display device 100.

For example, in the case that a horizontal width of a first light emitting area EA1 is large as shown in FIG. 3B, since the proportion of light reflected from the inclined portion 201a of the first electrode 201 among the light emitted from the light emitting layer 202 may be further reduced, there may be a greater limit to increasing the light extraction efficiency of the display device 100.

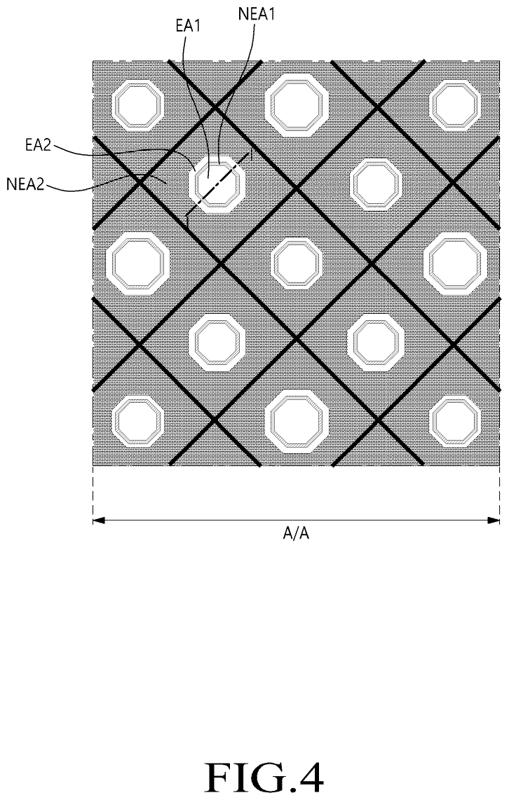

Hereinafter, it will be described a method for solving the above problems and maximizing light extraction efficiency according to an embodiment of the present disclosure with reference to a display device 100 shown in FIGS. 4 to 7.

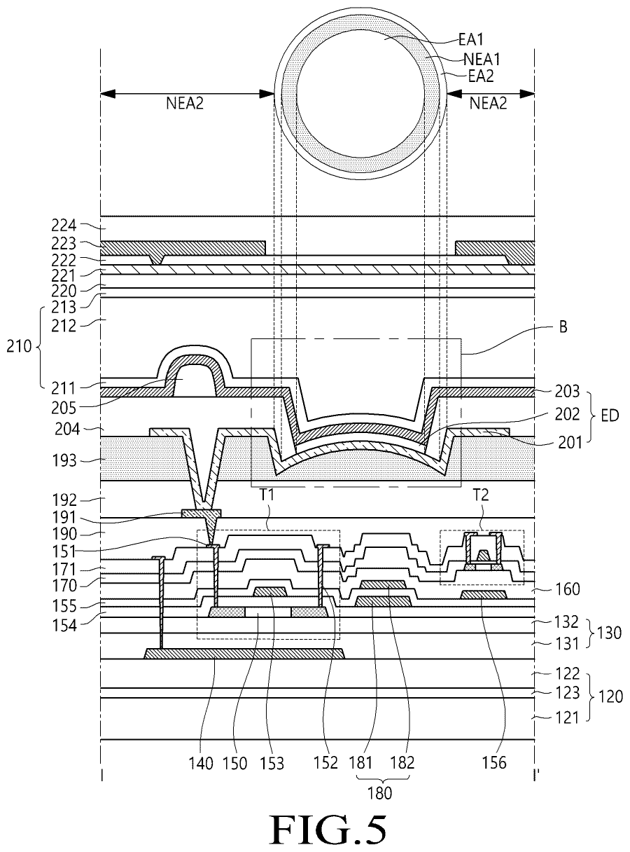

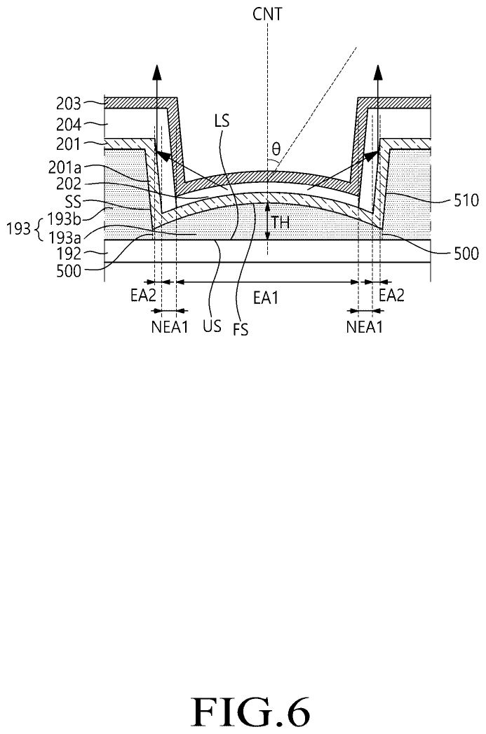

FIG. 4 illustrates an example of a planar structure of a display device according to embodiments of the present disclosure, FIG. 5 illustrates an example of the cross-sectional structure of II′ in FIG. 4, and FIG. 6 is an enlarged view of part B of FIG. 5.

Referring to FIG. 4, a display panel 110 according to embodiments of the present disclosure may have a structure in which one subpixel includes a plurality of light emitting areas EA1 and EA2.

Specifically, each subpixel disposed in an active area A/A may include a first light emitting area EA1. The first light emitting area EA1 may refer to an area where a first electrode 201, a light emitting layer 202 and a second electrode 203 are sequentially stacked.

Based on a plan view, the first light emitting area EA1 may be surrounded by a first non-emission area NEAL.

The first non-emission area NEA1 may be an area in a black state when the display panel is in an ON-state. Alternatively, the first non-emission area NEA1 may be an area with lower luminance than a first light emitting area EA1 and a second light emitting area EA2 due to light incident from at least one of the first light emitting area EA1 and the second light emitting area EA2.

Based on a plan view, the first non-emission area NEA1 may be surrounded by the second light emitting area EA2 included in one subpixel SP.

The first light emitting area EA1 and the second light emitting area EA2 may be areas which emit light of the same color.

The second light emitting area EA2 may be an area formed by reflection of light emitted from the light emitting element ED due to the inclined portion 201a of the first electrode 201 disposed on the inclined side of the second planarization layer 193.

A second non-emissive area NEA2 may be arranged to surround the second light emitting area EA2 in a plan view.

In some embodiments, as shown throughout the figures the first light emitting area EA1 overlaps with the light emitting layer 202 from a plan view. The second light emitting area EA2 overlaps with the second surface SS of the second portion 193b of the planarization layer 193 from a plan view. The first non-emission area NEA1 is disposed between the first light emitting area EA1 and the second light emitting area EA2 from a plan view.

The second non-emission area NEA2 may be an area between the second light emitting area EA2 of one subpixel and the second light emitting area EA2 of another adjacent subpixel.

Accordingly, the display panel 110 may include the inclined portion 201a of the first electrode 201 disposed in the opening area of the second planarization layer 193, so that each subpixel SP may have a plurality of light emitting areas.

As will be described later, as the second planarization layer 193 of the display panel 110 includes a first portion 193a having a convex upper surface (also referred to as a first surface FS; see FIG. 6), the amount of light directed to the inclined portion 201a of the first electrode 201 among the light emitted from the light emitting layer 202 may increase, and thus the luminance of the first and second light emitting areas EA1 and EA2 may further increase.

Since a display device 100 shown in FIGS. 5 and 6 may be the same as the display device described with reference to FIGS. 2 and 3 except differences of the structures of a second planarization layer 193, a first electrode 201, a light emitting layer 202 and a second electrode 203, it will be omitted the overlapping descriptions.

Referring to FIGS. 5 and 6, a second planarization layer 193 has a first portion 193a on a first planarization layer 192 having a convex upper surface in a direction perpendicular to the first planarization layer 192 (or in other words, the convex upper surface FS is opposite of the first planarization layer 192), and a second portion 193b disposed around the first portion 193a.

The first portion 193a may be defined as a part having a convex upper surface in a direction perpendicular to the first planarization layer 192 (or in a direction opposite of the first planarization layer 192). The first portion 193a has the first surface FS that has a curvature. The first surface FS of the first portion 193a is curved such that the thickness or the height TH of the first portion 193a is the thickest or highest at a center CNT portion of the first portion 193a.

The lower surface LS of the first portion 193a may contact the upper surface US of the first planarization layer 192. That is, the lower surface LS of the first portion 193a is opposite to and faces the upper surface US of the first planarization layer 192. Also, the lower surface LS of the first portion 193a directly contacts the upper surface US of the first planarization layer 192. The thickness TH may be defined by a distance between the first surface FS and the lower surface LS of the first portion 193a.

The first portion 193a may include a lower portion with a constant width in the horizontal direction. That is, the first portion 193a may have a side surface 500 perpendicular to the first planarization layer 192. Additionally, the upper surface of the first portion 193a may be spaced apart from the first planarization layer 192 by a height of the side surface 500 perpendicular to the first planarization layer 192. However, the present disclosure is not limited thereto, and the first portion 193a may not include a side surface 500 perpendicular to the first planarization layer 192. That is, the upper surface of the first portion 193a may contact the first planarization layer 192.

The first portion 193a may overlap the first light emitting area EA1. For example, the maximum horizontal width of the first portion 193a may be greater than the horizontal width of the first light emitting area EA1.

For example, the first portion 193a may at least partially overlap the second light emitting area EA2.

For example, the light emitting layer 202 may overlap with the first surface FS of the first portion 193a of the planarization layer from a plan view.

In the case that the first portion 193a has a side surface 500 perpendicular to the first planarization layer 192, the first portion 193a may contact the second portion 193b on a side surface 500 perpendicular to the first planarization layer 192. That is, the first portion 193a and the second portion 193b may be arranged to be connected.

If the first portion 193a does not have a side surface 500 perpendicular to the first planarization layer 192, the first portion 193a may be disconnected from the second portion 193b. That is, if the first portion 193a does not have a side surface 500 perpendicular to the first planarization layer 192, the first portion 193a may be located within the area where the second portion 193b is opened.

Here, if the first portion 193a of the second planarization layer 193 does not have a side surface 500 perpendicular to the first planarization layer 192, a length of an inclined side surface of the second portion 193b of the second planarization layer 193 may be longer compared to the case where the first portion 193a of the second planarization layer 193 has a side surface 500 perpendicular to the first planarization layer 192.

The horizontal width of the first portion 193a of the second planarization layer 193 may be different at the top and bottom of the first portion 193a. For example, the horizontal width of the first portion 193a may be smaller at the top than at the bottom of the first portion 193a. Here, as the second planarization layer 193 approaches the top of the first portion 193a, the horizontal width of the first portion 193a may become smaller. That is, the closer to the top of the first portion 193a of the second planarization layer 193, the smaller the horizontal width of the first portion 193a may be. That is, the first portion 193a may have a convex structure in an upward direction away from the first planarization layer 192.

The horizontal width of the first portion 193a of the second planarization layer 193 may gradually decrease. For example, the thickness of the first portion 193a of the second planarization layer 193 may gradually increase from an edge area to a center area of the first portion 193a. Accordingly, even if the distance from the center area of the first portion 193a to the inclined portion 201a of the first electrode 201 increases, the viewing angle, front luminance, and light extraction efficiency can be effectively improved.

The vertical height of the first portion 193a of the second planarization layer 193 may be a distance from the top surface of the first planarization layer 192 to a bottom surface of the first electrode 201. The vertical height of the first portion 193a may be greatest at the middle (i.e., center) of the first portion 193a. That, is, the thickness of the first portion 193a may be greatest at the center of the first portion 193a. The vertical height of the first portion 193a may become smaller toward the edge area of the first portion 193a. Additionally, the first portion 193a may have a structure symmetrical about an axis perpendicular to the first planarization layer 192 located in the center of the first portion 193a, but is not limited thereto.

The maximum vertical height of the first portion 193a may be smaller than a vertical height of the second portion 193b.

The second portion 193b may be placed on both sides of the first portion 193a.

In the case that the first portion 193a has a side surface 500 perpendicular to the first planarization layer 192, the second portion 193b may include an inclined side surface 510 (also referred to as a second surface SS; see FIG. 6) forming a specific slope with the first planarization layer 192 and a vertical side surface 500 perpendicular to the first planarization layer 192.

As described above, the second portion 193b may contact the first portion 193a at the vertical side surface 500 of the second portion 193b. That is, the vertical side surface 500 of the second portion 193b may be the same as the vertical side surface 500 of the first portion 193a.

If the first portion 193a does not have a side surface 500 perpendicular to the first planarization layer 192, the second portion 193b may have an inclined side surface 510 which forms a specific inclination with the first planarization layer 192.

The second portion 193b may have a constant height in the vertical direction except for the inclined side surface 510 or the vertical side surface 500 perpendicular to the first planarization layer 192. That is, the second portion 193b may have an upper surface parallel to the first planarization layer 192 in the horizontal direction.

Meanwhile, FIGS. 5 and 6 have illustrated a first portion 193a and the second portion 193b of the second planarization layer 193 disposed in one subpixel, the first portion 193a and the second portion 193b of the second planarization layer 193 may be disposed in each of a plurality of subpixels, and the size of the first portion 193a disposed in each of the plurality of subpixels may be different for each subpixel.

For example, the plurality of subpixels may include a red subpixel emitting red, a green subpixel emitting green, and a blue subpixel emitting blue. Here, a horizontal width of the first portion 193a included in the red subpixel, a horizontal width of the first portion 193a included in the green subpixel, and a horizontal direction of the first portion 193a included in the blue subpixel may be different from each other.

The first electrode 201 may be disposed on the first portion 193a and the second portion 193b of the second planarization layer 193.

For example, the first electrode 201 may be disposed along a convex upper surface of the first portion 193a of the second planarization layer 193. Since the first electrode 201 is disposed along the convex upper surface of the first portion 193a, the first electrode 201 may have a convex shape. In addition, the first electrode 201 may have a constant thickness on the first portion 193a. In some embodiments, the first electrode 201 is continuously and contiguously disposed on the second surface SS of the second portion 193b of the planarization layer 193 and the first surface FS of the first portion 193a of the planarization layer 193.

Meanwhile, as described above, the inclined portion 201a of the first electrode 201 may be disposed on the inclined side surface 510 of the second portion 193b of the second planarization layer 193.

In an embodiment, since the second portion 193b of the second planarization layer 193 has an inclined side surface 510, during the process of depositing the first electrode 201, a portion may flow down along the inclined side surface 510. Accordingly, a thickness of the first electrode 201 disposed on the upper surface of the first portion 193a may be greater than a thickness of the inclined portion 201a of the first electrode 201 disposed on the inclined side surface 510 of the second portion 193b. However, the embodiments of the present disclosure are not limited thereto.

In the case that the second portion 193b of the second planarization layer 193 does not have a vertical side surface 500 perpendicular to the first planarization layer 192, that is, the second portion 193b has only an inclined side surface 510, a length of the inclined side surface 510 of the second portion 193b of the second planarization layer 193 may be longer compared to a case in which the second portion 193b has both a vertical side surface 500 and an inclined side surface 510.

Accordingly, if the first portion 193a does not have a vertical side surface 500 perpendicular to the first planarization layer 192, the length of the inclined portion 201a of the first electrode 201 disposed on the inclined side surface 510 of the second portion 193b of the second planarization layer 193 may also be greater compared to a case with vertical side surface 500.

A bank layer 204 may be disposed in some areas on the first electrode 201. The bank layer 204 may cover a part of the convex shape of the first electrode 201 disposed on the first portion 193a of the second planarization layer 193.

The light emitting layer 202 may be disposed in a partial area on the first electrode 201 disposed on the first portion 193a of the second planarization layer 193. The light emitting layer 202 may be disposed along the convex shape of the first electrode 201, and thus the light emitting layer 202 may have a convex shape in at least a part of the area overlapping the first portion 193a. In some embodiments, the light emitting layer 202 is spaced apart from a second surface SS of the second portion 193b of the planarization layer 193 as shown in FIG. 6.

A second electrode 203 may be disposed on the light emitting layer 202. The second electrode 203 may be disposed along the shape of the light emitting layer 202, so that the second electrode 203 may have a convex shape in an area where the light emitting layer 202 has a convex shape.

A first encapsulation layer 211 may be disposed on the second electrode 203. Since the first encapsulation layer 211 may be disposed along the shape of the second electrode 203, the first encapsulation layer 211 may form a convex portion in an area where the second electrode 203 has a convex shape.

As described above, the first light emitting area EA1 may be defined as an area where the first electrode 201, the light emitting layer 202 and the second electrode 203 are sequentially stacked.

In this case, since the first electrode 201, the light emitting layer 202 and the second electrode 203 have a convex shape, the light emitting area may increase compared to the width of the first light emitting area EA1, so the luminance of the display device 100 can be increased. Additionally, since higher luminance can be obtained under the same current density, the light extraction efficiency of the display device 100 can be improved.

Hereinafter, it will be described the features in which the light extraction efficiency and luminance within the viewing angle of the display device 100 are improved as the second planarization layer 193 includes the first portion 193a with reference to the drawings.

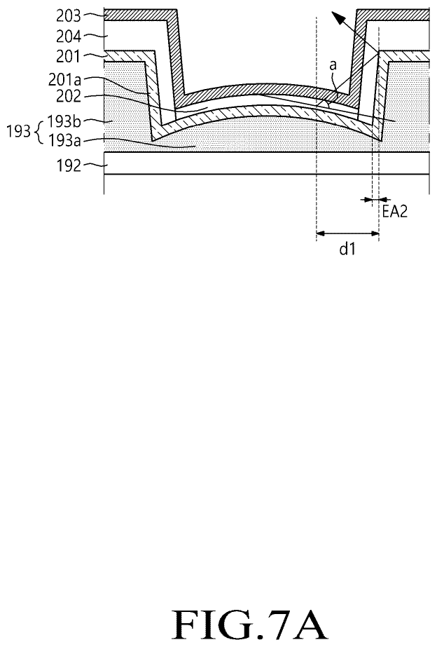

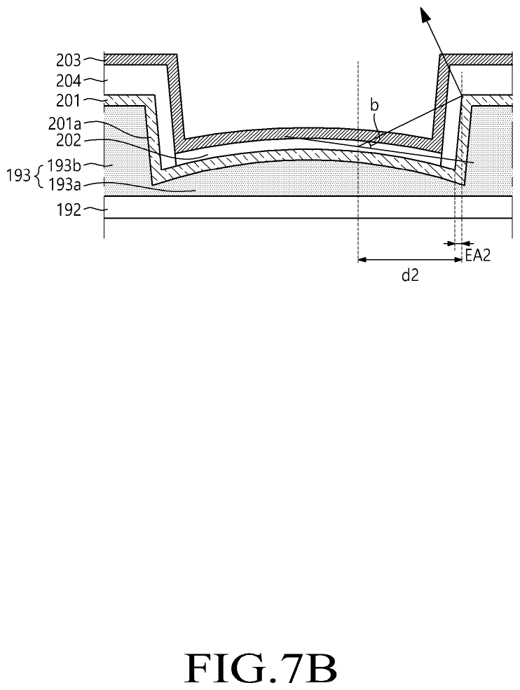

FIGS. 7A and 7B are diagrams for explaining optical characteristics of the display device shown in FIG. 6.

Referring to FIG. 7A, the first portion 193a of the second planarization layer 193 has a convex upper surface in a direction perpendicular to the first planarization layer 192. Accordingly, the light emitted from a point d1 away from the outer boundary of the second light emitting area EA2 may be reflected by a inclined portion 201a of the first electrode 201 even if the angle formed with the straight line tangent to the light emitting layer 202 at a point d1 away from the outer boundary of the second light emitting area EA2 is ‘a’ degree.

That is, compared to the display device 100 described with reference to FIG. 3A, since the light emitting layer 202 has a convex top surface, at a point d1 away from the outer boundary of the second light emitting area EA2, the light emitting layer 202 may emit more light toward the inclined portion 201a of the first electrode 201 on one side. Accordingly, the amount of light reflected from the inclined portion 201a of the first electrode 201 and emitted to the outside of the display device 100 may increase.

Referring to FIG. 7B, among the light emitted from the light emitting layer 202, the light with an angle of ‘b’ degree formed with a straight line tangent to the light emitting layer 202 at a point d2 away from the outer boundary of the second light emitting area EA2 may be reflected on the inclined portion 201a of the first electrode 201 even if the distance from the outer boundary of the second light emitting area EA2 is d2.

That is, compared to the display device 100 described with reference to FIG. 3B, the light emitting layer 202 has a convex top surface, so that even if the distance from the outer boundary of the second light emitting area EA2 is large, the light emitting layer 202 may emit light toward the inclined portion 201a of the first electrode 201 on one side. Accordingly, the amount of light reflected from the inclined portion 201a of the first electrode 201 and emitted to the outside of the display device 100 may increase.

As described above with reference to FIGS. 7A and 7B, compared to a case where the second planarization layer 193 does not include the first portion 193, in the case that the second planarization layer 193 includes the first portion 193a, the amount of light reflected through the inclined portion 201a of the first electrode 201 and traveling outward increases, so that the light extraction efficiency of the display device 100 may be increased.

In addition, compared to a case of where the second planarization layer 193 does not include the first portion 193a, the amount of light reflected by the inclined portion 201a of the first electrode 201 among the light emitted from the light emitting layer 202 may increase, so the luminance within the viewing angle range of the display device 100 may increase. That is, luminance may increase at the angle at which the user looks at the display device 100 according to the path of the light reflected from the inclined portion 201a of the first electrode 201.

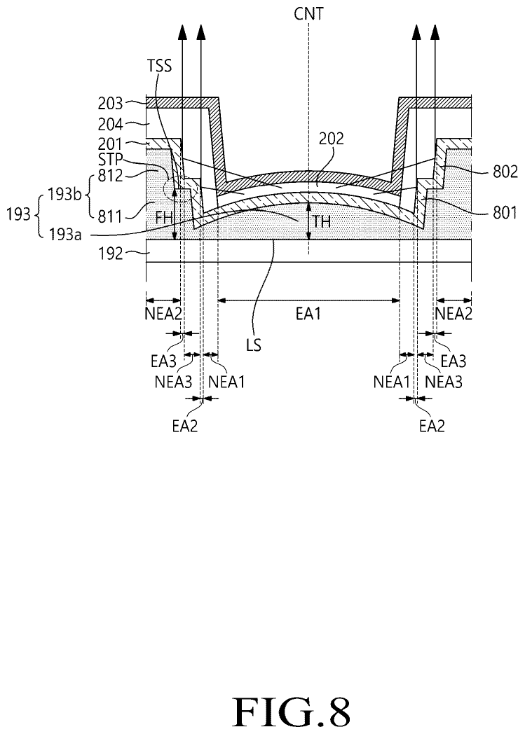

FIGS. 8 to 10 illustrate another examples of part B of FIG. 5.

In describing this embodiment, there will be omitted the description of components which are the same as or correspond to the previous embodiment. Hereinafter, the display device according to an embodiment will be described with reference to the drawings.

Referring to FIG. 8, a second planarization layer 193 of a display device 100 according to an embodiment of the present disclosure may include a first portion 193a and a second portion 193b disposed around the first portion 193a in an area overlapping the first light emitting area EA1. The first portion 193a may be the same as the first portion 193a previously described with reference to FIGS. 5 and 6.

The second portion 193b may have a stepped structure or a staircase structure as shown in FIG. 8.

The second portion 193b may include a first layer 811 disposed on a first planarization layer 192 and a second layer 812 disposed on the first layer 811.

The first layer 811 and the second layer 812 may each have an inclined side surface. In addition, an angle formed by the inclined side surface of the first layer 811 with the first planarization layer 192 may be the same as an angle formed between the inclined side surface of the second layer 812 and the first planarization layer 192. However, the present disclosure may be not limited thereto, and the angle formed by the inclined side surface of the first layer 811 with the first planarization layer 192 may be different from an angle formed by the inclined side surface of the second layer 812 with the first planarization layer 192. For example, the angle formed by the inclined side surface of the second layer 812 with the first planarization layer 192 may be smaller than the angle formed by the inclined side surface of the first layer 811 with the first planarization layer 192.

In the case that the angle formed by the inclined side surface of the second layer 812 with the first planarization layer 192 is smaller than the angle formed by the inclined side surface of the first layer 811 with the first planarization layer 192, if the first layer 811 and the second layer 812 have the same vertical height, a horizontal width of the second layer 812 may be larger than a horizontal width of the first layer 811.

Therefore, the horizontal width of the second light emitting area EA2 may increase. In addition, as the horizontal width of the second light emitting area EA2 increases, the amount of light which can be reflected by the first electrode 201 and emitted to the outside may increase, thereby further increasing the light extraction efficiency of the display device 100.

A side of the first layer 811 of the second portion 193b may partially contact one side of the first portion 193a. An upper surface of the first layer 811 of the second portion 193b may partially contact a lower surface of the second layer 812 of the second portion 193b.

Among the upper surfaces of the first layer 811 of the second portion 193b, there may be a part which does not contact the lower surface of the second layer 812 of the second portion 193b. That is, the first layer 811 and the second layer 812 each have a trapezoid-like cross-section as shown in FIG. 8. The first layer 811 and the second layer 812 are different in size creating a step STP in the second portion 193b. The step STP may have a first height FH defined between the distance between the lower surface LS of the second planarization layer 193 and a top surface TSS of the first layer 811. In some embodiments, the first height FH of the step STP is greater than a height TH of thickest portion at the center CNT of the first portion 193a of the planarization layer 193.

A first electrode 201 may be disposed in an area of the upper surface of the first layer 811 of the second portion 193b which does not contact the lower surface of the second layer 812 of the second portion 193b.

The first electrode 201 may be disposed in an area of a side surface of the first layer 811, a side surface of the second layer 812 and the upper surface of the second portion 193b which do not contact the lower surface of the second layer 812.

The first electrode 201 may include a first inclined portion 801 of the first electrode 201 disposed on a side surface of the first layer 811 of the second portion 193b, and a second inclined portion 802 of the first electrode 201 disposed on a side surface of the second layer 812 of the second portion 193b.

The light emitted from the light emitting layer 202 may be reflected from the first inclined portion 801 of the first electrode 201 or the second inclined portion 802 of the first electrode 201 to be emitted outside of the display device 100.

The light reflected from the first inclined portion 801 of the first electrode 201 among the light emitted from the light emitting layer 202 may travel to the outside of the display device 100, so that an area in which the first inclined portion 801 of the first electrode 201 is disposed may be a second light emitting area EA2. Similarly, some of the light emitted from the light emitting layer 202 may be reflected by the second inclined portion 802 of the first electrode 201 and travel to the outside of the display device 100, so that an area where the second inclined portion 802 of the first electrode 201 is disposed may be a third light emitting area EA3.

The first electrode 201 disposed in the area between the first inclined portion 801 of the first electrode 201 and the second inclined portion 802 of the first electrode 201 may not reflect the light emitted from a light emitting layer 202. Accordingly, the area between the second light emitting area EA2 and the third light emitting area EA3 may be a third non-emission area NEA3.

For example, based on a plan view, the third non-emission area NEA3 may surround the second light emitting area EA2, and the third light emitting area EA3 may surround the third non-emission area NEA3. Additionally, the second non-emission area NEA2 may surround the third light emitting area EA3.

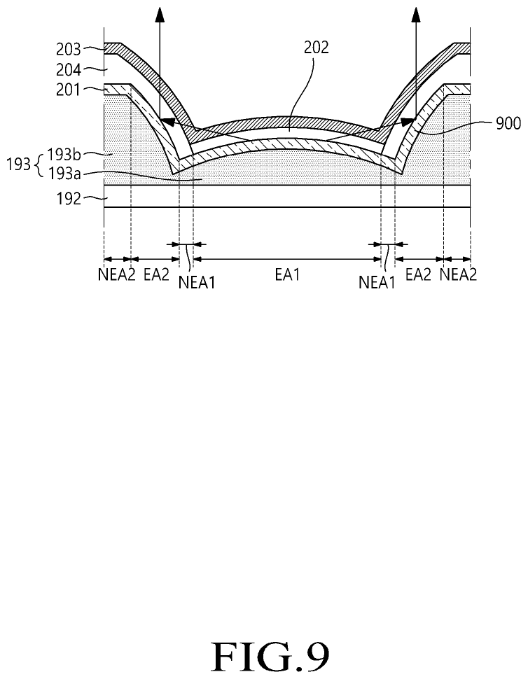

Referring to FIG. 9, the second planarization layer 193 of the display device 100 according to an embodiment of the present disclosure may include a first portion 193a and a second portion 193b disposed around the first portion 193a in the area overlapping with the first light emitting area EA1.

The first portion 193a may be the same as the first portion 193a previously described with reference to FIGS. 5 and 6.

Referring to FIG. 9, the second portion 193b may have a partially convex upper surface in a direction perpendicular to the first planarization layer 192.

The maximum height of the second portion 193b in the vertical direction may be the same as the height of the second portion 193b described with reference to FIGS. 5 and 6.

Since the second portion 193b has a partially convex upper surface, the first electrode 201 disposed on the convex upper surface of the second portion 193b may also have a convex shape.

That is, the first electrode 201 may include a convex portion 900, and the convex portion 900 may have a convex upper surface in a direction perpendicular to the first planarization layer 192.

Since the convex portion 900 has a convex upper surface, a length of an upper surface of the convex portion 900 may be greater than a length of an upper surface of an inclined portion 201a of the first electrode 201 in the case that the inclined portion 201a of the first electrode 201 has an inclination of a specific angle.

Since the length of the upper surface of the convex portion 900 is greater than a length of an upper surface of an inclined portion 201a of the first electrode 201 in the case that the inclined portion 201a of the first electrode 201 has an inclination of a specific angle, there may further increase an area where light emitted from the light emitting layer 202 can be reflected by the inclined portion 201a of the first electrode 201. Accordingly, the light extraction efficiency of the display device 100 may further increase.

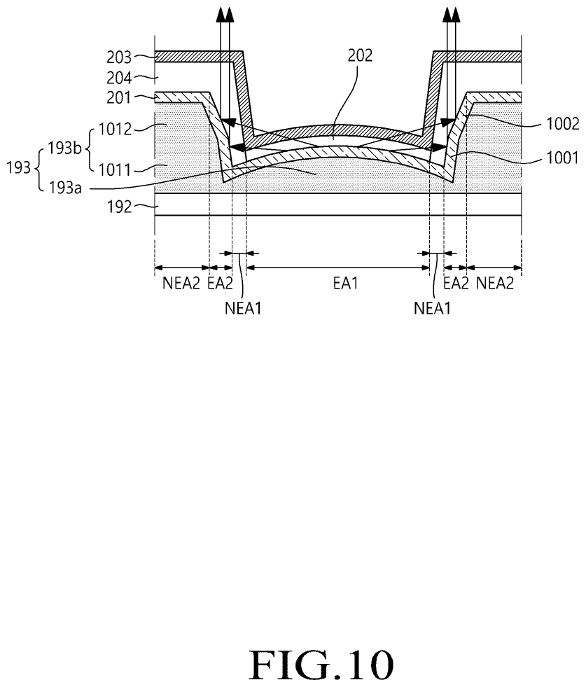

Referring to FIG. 10, a second planarization layer 193 of the display device 100 according to an embodiment of the present disclosure may include a first portion 193a and a second portion 193b disposed around the first portion 193a in the area overlapping with the first light emitting area EA1. The first portion 193a may be the same as the first portion 193a previously described with reference to FIGS. 5 and 6.

The second portion 193b may have a stacked structure with different angles from the first planarization layer 192, as shown in FIG. 10.

Specifically, the second portion 193b may include a first inclined portion 1011 having an inclined side surface and a second inclined portion 1012 disposed on the first inclined portion 1011 and having an inclined side surface.

The upper surface of the first inclined portion 1011 may be in contact with a lower surface of the second inclined portion 1012. That is, the first inclined portion 1011 may be connected to the second inclined portion 1012, and may be made of the same material.

The angle formed by the inclined side surface of the second inclined portion 1012 with the first planarization layer 192 may be smaller than an angle formed by the inclined side surface of the first inclined portion 1011 with the first flattening layer 192.

The vertical height of the second portion 193b may be the same as the height of the second portion 193b described with reference to FIGS. 5 and 6.

A first electrode 201 may be disposed on the first inclined portion 1011 and the second inclined portion 1012 of the second portion 193b.

Specifically, the first electrode 201 may include a third inclined portion 1001 of the first electrode 201 and a fourth inclined portion 1002 of the first electrode 201. The third inclined portion 1001 of the first electrode 201 may be disposed on the first inclined portion 1011 of the second portion 193b, and the fourth inclined portion 1002 of the first electrode 201 may be disposed on the second inclined portion 1012 of the second portion 193b.

An angle formed by the fourth inclined portion 1002 of the first electrode 201 with the first planarization layer 192 may be smaller than the angle formed by the third inclined portion 1001 of the first electrode 201 with the first planarization layer 192.

Light emitted from the light emitting layer 202 may be reflected from the third inclined portion 1001 and the fourth inclined portion 1002 of the first electrode 201 and emitted to the outside of the display device 100.

Since the angle formed by the fourth inclined portion 1002 of the first electrode 201 with the first planarization layer 192 is smaller than the angle formed by the third inclined portion 1001 of the first electrode 201 with the first planarization layer 192, if the third inclined portion 1001 of the first electrode 201 and the fourth inclined portion 1002 of the first electrode 201 have the same vertical height, a horizontal width of the fourth inclined portion 1002 of the first electrode 201 may be greater than a horizontal width of the third inclined portion 1001 of the first electrode 201.

Therefore, compared to a case where the second portion 193b has a surface inclined at a constant angle, the horizontal width of the second light emitting area EA2 may increase. As the width of the second light emitting area EA2 increases, the amount of light reflected by the first electrode 201 and emitted to the outside may increase, thereby further increasing the light extraction efficiency of the display device 100.

Hereinafter, it will be described a method of manufacturing the display device 100 according to an embodiment of the present disclosure.

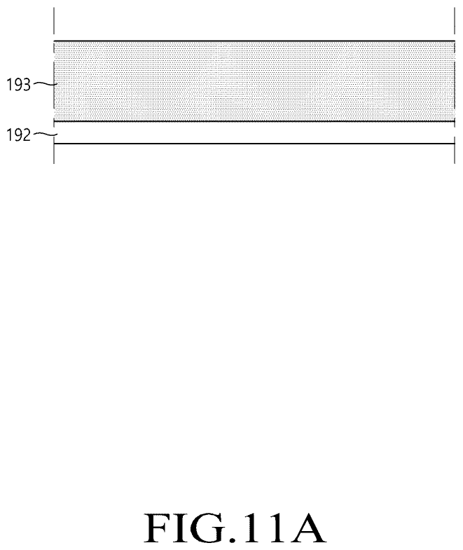

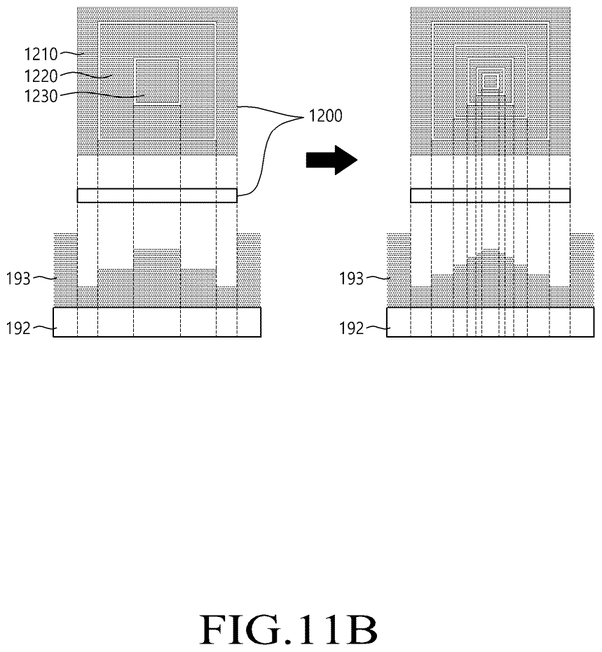

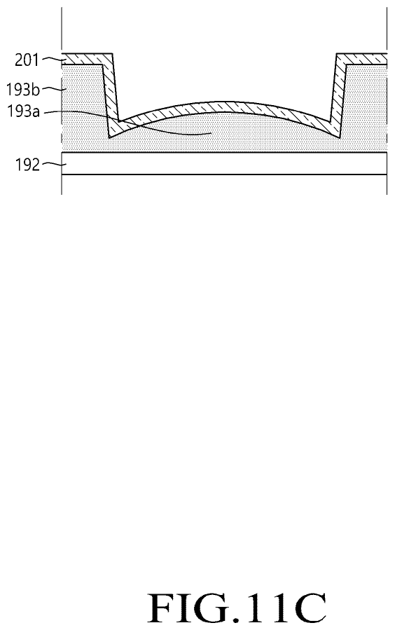

FIGS. 11A to 11C are diagrams for explaining a method of manufacturing a display device according to embodiments of the present disclosure.

Referring to FIG. 11A, a first planarization layer 192 may be formed on a substrate 120.

There may be arranged various buffer layers, insulating layers and transistors between the substrate 120 and the first planarization layer 192, as described above. However, for convenience of explanation below, description will begin with a step forming the first planarization layer 192.

A second planarization layer 193 may be formed on the first planarization layer 192. Here, the second planarization layer 193 may have an upper surface horizontally parallel to the first planarization layer 192.

The second planarization layer 193 may be partially removed after forming the second planarization layer 193.

Referring to FIG. 11B, the second planarization layer 193 may be selectively removed using an etching mask 1200.

The etching mask 1200 may be divided into a plurality of square border areas as shown in FIG. 11B. There may be a gap between each square border area through which light passes.

Each square border area may transmit a portion of light incident from top to bottom of the etching mask 1200, and each square border area may have a different light transmittance.

For example, the etching mask 1200 may include a first area 1210 and a second region 1220 inside the first area 1210. The horizontal widths of the first area 1210 and the second area 1220 may be different from each other, however, is not limited thereto.

The etching mask 1200 may have a transmittance of x % in the first area 1210 and a transmittance of y % in the second area 1220. Here x may be greater than y.

If x is greater than y, more light incident in a direction perpendicular to the etching mask 1200 may pass through the etching mask 1200 through the first area 1210 than through the second area 1220. Therefore, in the process of etching the second planarization layer 193 by irradiating light, more of the second planarization layer 193 may be removed by etching in an area corresponding to the first area 1210.

Accordingly, a vertical height of the second planarization layer 193 in the area corresponding to the first area 1210 may be smaller than a vertical height of the second planarization layer 193 in an area corresponding to the second area 1220.

Similarly, the etching mask 1200 may include a third area 1230 inside the second area 1220. The horizontal widths of the second area 1220 and the third area 1230 may be different from each other.

The etching mask 1200 may have a transmittance of y % in the second area 1220 and a transmittance of z % in the third area 1230. Here y may be greater than z.

If y is greater than z, more light incident in a direction perpendicular to the etching mask 1200 may pass through the etching masking 1200 in the second area 1220 than in the third area 1230. Therefore, in the process of etching the second planarization layer 193 by irradiating light, more of the second planarization layer 193 may be removed from an area corresponding to the second area 1220.

Accordingly, a vertical height of the second planarization layer 193 in the area corresponding to the second area 1220 may be smaller than a vertical height of the second planarization layer 193 in an area corresponding to the third area 1230.

In this way, there may adjust an etching rate of the second planarization layer 193 corresponding to each square border area by setting the transmittance of the inner square border area of the etching mask 1200 to be smaller. There may be etched so that the vertical height of the second planarization layer 193 corresponding to the inner area among the square border areas is larger.

In addition, as shown in FIG. 11B, if the number of square border areas with different transmittances included in the etching mask 1200 is increased, the areas with different transmittances within the etching mask 1200 may be arranged more tightly.

As shown in FIG. 11B, as the number of square border areas with different transmittances increases, the upper surface of the second planarization layer 193 has an increasingly convex upper surface in the direction perpendicular to the first planarization layer 192.

Referring to FIG. 11C, a first electrode 201 may be formed on the second planarization layer 193.

The first electrode 201 may be formed on an area where the second planarization layer 193 has been partially removed.

As described above, as part of the second planarization layer 193 is removed, there may be formed areas where the second planarization layer 193 has different vertical heights or parts with a convex upper surface, and the first electrode 201 on the second planarization layer 193 may have a convex upper surface.

Although not shown in FIG. 11C, a light emitting layer 202 may be disposed in some areas on the first electrode 201. The light emitting layer 202 may be disposed along the upper surface of the first electrode 201, and thus may have a convex shape. That is, as described above, more light emitted from the light emitting layer 202 having a convex shape can be directed to an inclined portion 201a of the first electrode 201. Accordingly, the amount of light reflected by the inclined portion 201a of the first electrode 201 and emitted to the outside of the display device 100 may increase, thereby increasing the light extraction efficiency of the display device 100.

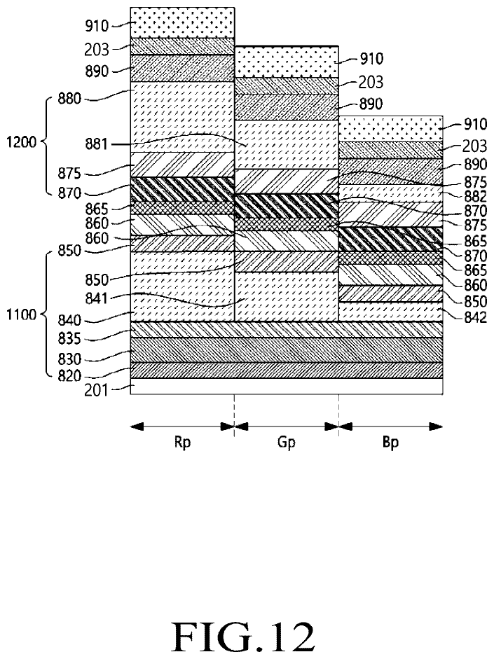

FIG. 12 illustrates an example of a light emitting device structure of a display device according to an embodiment of the present disclosure.

Referring to FIG. 12, the display device may include a light emitting element ED.

The light emitting element ED may be include a first electrode 201 formed on a substrate in which a red subpixel region Rp, a green subpixel region Gp and a blue subpixel region Bp are defined, a first organic emission layer consisting of a hole injection layer (820; HIL), a first hole transport layer (830; 1st HTL), a first hole control layer (835; 1st HCL), a first red emission layer (840; 1st Red EML), a first green emission layer (841; 1st Green EML) and a first blue emission layer (842; 1st Blue EML), a second organic emission layer consisting of a first electron transport layer (850; 1st ETL), a first charge generation layer (860; N-CGL), a second charge generation layer (865; P-CGL), a second hole transport layer (870; 2nd HTL), a second hole control layer (875; 2nd HCL), a second red emission layer (880, Red EML), a second green emission layer (881; 2nd Green EML) and a second blue emission layer (882; 2nd Blue EML), a second electron transporting layer (890, 2nd ETL), a second electrode 203, and a capping layer (910, CPL).

In addition, the light emitting element ED according to an embodiment of the present disclosure may be an organic light emitting device having a two-stack structure in which a first light emitting unit (1100) including a first organic light emitting layer and a second light emitting unit (1200) including a second organic light emitting layer are stacked between the first electrode 201 and the second electrode 203.

For example, in the light emitting element ED according to an embodiment of the present disclosure, the first light emitting unit or a first light emitting part 1100 may include a first organic light emitting layer consisting of a hole injection layer 820, a first hole transport layer 830, a first hole control layer 835, a first red emission layer 840, a first green emission layer 841 and a first blue emission layer 842, and a first electron transport layer 850.

In the light emitting element ED according to an embodiment of the present disclosure, the second light emitting unit or a second light emitting part 1200 may include a second organic light emitting layer consisting of a second hole transport layer 870, a second hole control layer 875, a second red emission layer 880, a second green emission layer 881 and a second blue emission layer 882, and a second electron transport layer 890.

The light emitting device according to an embodiment of the present disclosure may include a first charge generation layer 860, which is an n-type charge generation layer and a second charge generation layer 865, which is a p-type charge generation layer between the first light emitting unit 1100 and the second light emitting unit 1200.

In a display device including an organic light emitting device according to an embodiment of the present disclosure, there may be arranged a gate line and a data line which cross each other on the substrate to define each pixel area, and a power line which extends parallel to any one of the gate line and the data line in each pixel area. In addition, in each pixel area, there may be disposed a switching thin film transistor connected to the gate line and data line and a driving thin film transistor connected to the switching thin film. The driving thin film transistor may be connected to a first electrode 201.

The first electrode 201 may be located on the substrate to correspond to each of the red subpixel region (Rp), green subpixel region (Gp) and blue subpixel region (Bp), and may be made of a reflective electrode.

The hole injection layer 820 may be positioned on the first electrode 810 to correspond to all of the red subpixel region (Rp), green subpixel region (Gp) and blue subpixel region (Bp).

The hole injection layer 820 may facilitate hole injection, and may contain at least one of HATCN (1,4,5,8,9,11-hexaazatriphenylene-hexanitrile), CuPc (cupper phthalocyanine), PEDOT (poly(3,4)-ethylenedioxythiophene), PANI (polyaniline), and NDP (N,N-dinaphthyl-N,N′-diphenylbenzidine), but is not limited thereto.

The first hole transport layer 830 and the second hole transport layer 870 may be formed to correspond to all of the red subpixel area (Rp), green subpixel area (Gp), and blue subpixel area (Bp), respectively, The first hole transport layer 830 may be located on the hole injection layer 820, and the second hole transport layer 870 may be located on the second charge generation layer 865.

The first hole transport layer 830 and the second hole transport layer 870 may facilitate the transport of holes, and may contain at least one of NPD (N,N-dinaphthyl-N,N′-diphenylbenzidine), TDP (N,N′-bis-(3-methylphenyl)-N,N′-bis-(phenyl)-benzidine, s-TAD, and MTDATA (4,4′,4″-Tris(N-3-methylphenyl-N-phenyl-amino)-triphenylamine), but is not limited thereto.

In the light emitting element ED according to an embodiment of the present disclosure, the first hole control layer 835 may be positioned on the first hole transport layer 830 to correspond to all of the red subpixel area (Rp), green subpixel area (Gp) and blue subpixel area (Bp).

The second hole control layer 875 may be located on the second hole transport layer 870 to correspond to all of the red subpixel region (Rp), green subpixel region (Gp), and blue su-pixel region (Bp).

Since holes have higher mobility characteristics than electrons at high temperatures, the first hole control layer 835 and the second hole control layer 875 may prevent a phenomenon in which holes pass through a first organic light emitting layer including a first red emission layer 840, a first green emission layer 841 and a first blue emission layer 842 and a second organic light emitting layer including a second red emission layer 880, a second green emission layer 881 and a second blue emission 882, which are regions where electrons and holes recombine to emit light, and move to the first electron transport layer 850 and the second electron transport layer 890, thereby leaving the light emitting area. The first hole control layer 835 and the second hole control layer 875 may be made of a material such as carbazole derivative, triarylamine derivative, or triamine derivative. For example, the first hole control layer 835 and the second hole control layer 875 may be made of at least one of TPD (N,N′-Bis(3-methylphenyl)-N,N′-bis(phenyl)-benzidine), α-NPB(BisThe first hole control layer 835 and the second hole control layer 875 may be made of the same material among the materials described above, and the holes in the first light-emitting unit 1100 and the second light-emitting unit 1200 Considering the mobility characteristics, it may be made of different materials among the materials described above. Alternatively, the first hole control layer 835 and the second hole control layer 875 may be made of different materials among the materials described above in consideration of the hole mobility characteristics in the first light emitting unit 1100 and the second light emitting unit 1200.

The first red emission layer 840 may be located in the red subpixel region (Rp) on the first hole transport layer 830, and the second red emission layer 880 may be located in the red subpixel region (Rp) on the second hole transport layer 870. The first red emission layer 840 and the second red emission layer 880 may each include a light emitting material emitting red light, and the light emitting material may be formed using a phosphorescent material or a fluorescent material.

As an example, the first red emission layer 840 and the second red emission layer 880 may contain a host material including CBP (4,4′-bis(carbozol-9-yl)biphenyl) or mCP (1,3-bis(N-carbozolyl)benzene), or may be made of a phosphorescent material containing a dopant including one or more of PQIr (acac) (bis(1-phenylquinoline) acetylacetonate iridium), PQIr (tris (1-phenylquinoline) iridium) and PtOEP (octaethylporphyrin platinum). Alternatively, the first red emission layer 840 and the second red emission layer 880 may be made of a fluorescent material containing PBD:Eu(DBM)3(Phen) or Perylene, but are not limited thereto.

The first green emission layer 841 may be located in the green subpixel region (Gp) on the first hole transport layer 830, and the second green emission layer 881 may be located in the green subpixel region (Gp) on the second hole transport layer 870. The first green emission layer 841 and the second green emission layer 881 may each include a light emitting material emitting green light, and the light emitting material may be formed using a phosphorescent material or a fluorescent material.

As an example, the first green emission layer 841 and the second green emission layer 881 may contain a host material including CBP or mCP, or may be made of a phosphorescent material containing a dopant materials such as iridium complex containing Ir(ppy)3 (fac tris(2-phenylpyridine)iridium). Alternatively, the first green emission layer 841 and the second green emission layer 881 may be made of a fluorescent material containing Alq3(tris(8-hydroxyquinolino)aluminum), but are not limited thereto.

The first blue emission layer 842 may be located in the blue subpixel region (Bp) on the first hole transport layer 830, and the second blue emission layer 882 may be located in the blue subpixel region (Bp) on the second hole transport layer 870. The first blue emission layer 842 and the second blue emission layer 882 may each include a light emitting material emitting blue light, and the light emitting material may be formed using a phosphorescent material or a fluorescent material.

As an example, the first blue emission layer 842 and the second blue emission layer 882 may contain a host material including CBP or mCP, or may be made of a phosphorescent material containing a dopant materials containing (4,6-F2ppy)2Irpic, but are not limited thereto. In addition, the first blue emission layer 842 and the second blue emission layer 882 may be made of fluorescent substance containing any one of spiro-DPVBi, spiro-6P, distylbenzene (DSB), distrylarylene (DSA), PFO-based polymer, and PPV-based polymer, but are not limited thereto.

The first electron transport layer 850 may be located on the first red emission layer 840, the first green emission layer 841 and the first blue emission layer 842 to correspond to all of the red subpixel region (Rp), green subpixel region (Gp) and blue subpixel region (Bp). In addition, the second electron transport layer 890 may be located on the second red emission layer 880, the second green emission layer 881 and the second blue emission layer 882 to correspond to all of the red subpixel region (Rp), green subpixel region (Gp) and blue subpixel region (Bp).

The first electron transport layer 850 and the second electron transport layer 890 may transport and inject electrons, and the thickness of the first electron transport layer 850 and the second electron transport layer 890 may be adjusted considering electron transport characteristics.

The first electron transport layer 850 and the second electron transport layer 890 may facilitate the transport of electrons, and may made of at least one of Alq3 (tris(8-hydroxyquinolino)aluminum), PBD (2-(4-biphenylyl)-5-(4-tert-butylpheny)-1,3,4oxadiazole), TAZ, spiro-PBD, BAlq, and SAlq, but are not limited thereto.

It is possible to additionally configure an electron injection layer (EIL) separately on the second electron transport layer 890.

The electron injection layer (EIL) may utilize Alq3 (tris(8-hydroxyquinolino)aluminum), PBD (2-(4-biphenylyl)-5-(4-tert-butylpheny)-1,3,4oxadiazole), TAZ, spiro-PBD, BAlq or SAlq, but is not limited thereto.

Here, the structure is not limited according to the embodiment of the present disclosure, there may be omitted at least one of the hole injection layer 820, the first hole transport layer 830, the second hole transport layer 870, the first electron transport layer 850, the second electron transport layer 890, and the electron injection layer (EIL). In addition, at least one of the first hole transport layer 830, the second hole transport layer 870, the first electron transport layer 850, the second electron transport layer 890 and the electron injection layer (EIL) may be e formed of two or more layers.

The first charge generation layer 860 may be located on the first electron transport layer 850 to correspond to all of the red subpixel region (Rp), green subpixel region (Gp) and blue subpixel region (Bp), and the second charge generation layer 865 may be located on the first charge generation layer 860 to correspond to all of the red subpixel region (Rp), green subpixel region (Gp) and blue subpixel region (Bp). The first charge generation layer 860 and the second charge generation layer 865 may have an NP junction structure.

Referring to FIG. 12, the first charge generation layer 860 and the second charge generation layer 865 may be located between the first light emitting unit 1100 and the second light emitting unit 1200. In addition, the first charge generation layer 860 and the second charge generation layer 865 may adjust the charge balance between the two light emitting units of the first light emitting unit 1100 and the second light emitting unit 1200.

The first charge generation layer 860 may serve as an n-type charge generation layer (n-CGL) which assists the injection of electrons into the first light emitting unit 1100 located below the first charge generation layer 860. The second charge generation layer 865 may serve as a p-type charge generation layer (p-CGL) which assists injection of holes into the second light emitting unit 1200 located on top of the second charge generation layer 865.

For example, the first charge generation layer 860, which is an n-type charge generation layer (n-CGL) for injecting electrons, may be made of an alkali metal, an alkali metal compound or an organic material acting as electron injectors, or a compound thereof. Additionally, the host material of the first charge generation layer 860 may be made of the same material as that of the first electron transport layer 850 and the second electron transport layer 890. For example, there may be composed of a mixed layer in which an organic material such as an anthracene derivative is doped with a dopant such as lithium (Li), but is not limited thereto.

The second charge generation layer 865 may be located on the first charge generation layer 860. The second charge generation layer 865 may function as a p-type charge generation layer (p-CGL) acting as a hole injectors, and the host material of the second charge generation layer 865 may be made of the same material as that of the first hole injection layer 820, the first hole transport layer 830 and the second hole transport layer 870. For example, the second charge generation layer 865 may be composed of a mixed layer in which organic materials such as HATCN (1,4,5,8,9,11-hexaazatriphenylene-hexanitrile), CuPc (cupper phthalocyanine) and TBAHA (tris(4-bromophenyl)aluminum hexacholroantimonate) are doped with p-type dopant, but is not limited thereto. In addition, the p-type dopant may be made of either F4-TCNQ or NDP-9, but is not limited thereto.

The second electrode 203 may be located on the second electron transport layer 890 to correspond to all of the red subpixel region (Rp), green subpixel region (Gp) and blue subpixel region (Bp). For example, the second electrode 203 may be made of an alloy of magnesium and silver (Mg:Ag), and may have transflective characteristics. For example, the light emitted from the organic light emitting layer may be displayed to the outside through the second electrode 203. Since the second electrode 203 has transflective characteristics, a part of the light may be directed to the first electrode 201 again.

In this way, due to a micro cavity effect in which repetitive reflection occurs between the first electrode 201 and the second electrode 203 acting as a reflective layer, the light may be repeatedly reflected within the cavity between the first electrode 201 and the second electrode 203, thereby increasing light efficiency.

In addition, it is possible to form the first electrode 201 as a transmission electrode and the second electrode 203 as a reflection electrode so that the light from the organic light emitting layer is displayed to the outside through the first electrode 201.

The capping layer 910 may be located on the second electrode 203. The capping layer 910 may increase the light extraction effect in the organic light emitting device. The capping layer 910 may be made of one of materials of a first hole transport layer 830, a second hole transport layer 870, a first electron transport layer 850, a second electron transport layer 890, and a host materials of a first red emission layer 840, a second red emission layer 880, a first green emission layer 841, a second green emission layer 881, a first blue emission layer 842, and the second blue emission layer 882, but are not limited thereto. Additionally, the capping layer 910 can be omitted.

Hereinafter, it will be described various configurations of a display device capable of increasing light extraction efficiency according to an embodiment of the present disclosure.

According to an embodiment of the present disclosure, a display device may further include a first electrode disposed on a part of the first portion and the second portion, and the first electrode may have a convex shape on the first portion.

According to an embodiment of the present disclosure, the first electrode may include an inclined portion in some area on the second portion, and an area where the inclined portion of the first electrode is disposed may overlap with a second light emitting area.

According to an embodiment of the present disclosure, a display device further may include a light emitting layer disposed on the first electrode, and the light emitting layer may have a convex shape in a region overlapping the first portion.

According to an embodiment of the present disclosure, a thickness of the first portion may be greatest at the center of the first portion.

According to an embodiment of the present disclosure, the second portion may have a staircase structure.

According to an embodiment of the present disclosure, the second portion may have a partial convex upper surface in a direction perpendicular to the first planarization layer.

According to an embodiment of the present disclosure, the second portion may include a portion forming a first angle with the first planarization layer and a portion forming a second angle smaller than the first angle.

According to an embodiment of the present disclosure, a thickness of the first portion may gradually increase from an edge area of the first portion to a center of the first portion.

According to an embodiment of the present disclosure, a plurality of subpixels may include a first subpixel emitting red, a second subpixel emitting green and a third subpixel emitting blue. A horizontal widths of the first portions of the second planarization layer included in each of the first subpixel, the second subpixel, and the third subpixel may be different from each other.

According to an embodiment of the present disclosure, a display device may further include a first electrode disposed on the second planarization layer, and the first electrode may have a convex shape on the convex portion.

According to an embodiment of the present disclosure, a display device may further include a light emitting layer disposed on the first electrode, and the light emitting layer may have a convex shape in a region overlapping the convex portion.

According to an embodiment of the present disclosure, a thickness of the convex portion may be greatest at the center of the convex portion.

According to an embodiment of the present disclosure, a thickness of the convex portion may gradually increase from an edge area of the convex portion to a center of the convex portion.

According to an embodiment of the present disclosure, a plurality of subpixels may include a first subpixel emitting red, a second subpixel emitting green and a third subpixel emitting blue. A horizontal widths of the convex portions of the second planarization layer included in each of the first subpixel, the second subpixel, and the third subpixel may be different from each other.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure. Thus, the scope of the present disclosure is not limited to the embodiments shown, but is to be accorded the widest scope consistent with the claims.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate on which a plurality of subpixels is disposed, each of the plurality of subpixels including a first light emitting area and a second light emitting area surrounding the first light emitting area;
a first planarization layer on the substrate; and
a second planarization layer which is disposed on the first planarization layer, and includes a first portion having a convex upper surface in a direction perpendicular to the first planarization layer in an area overlapping the first light emitting area and a second portion disposed around the first portion.

2. The display device of claim 1, further comprising a first electrode disposed on a part of the first portion and the second portion,
wherein the first electrode has a convex shape on the first portion.

3. The display device of claim 2, wherein the first electrode has an inclined portion in an area on the second portion, and the area in which the inclined portion of the first electrode is disposed overlaps the second light emitting area.

4. The display device of claim 2, further comprising a light emitting layer disposed on the first electrode,
wherein the light emitting layer has a convex shape in an area overlapping with the first portion.

5. The display device of claim 1, wherein a thickness of the first portion is greatest at the center of the first portion.

6. The display device of claim 1, wherein the second portion has a staircase structure.

7. The display device of claim 1, wherein the second portion has an upper surface at least partially convex in a direction perpendicular to the first planarization layer.

8. The display device of claim 1, wherein the second portion includes a portion forming a first angle with the first planarization layer and a portion forming a second angle smaller than the first angle.

9. The display device of claim 1, wherein a thickness of the first portion gradually increases from an edge area of the first portion to a center of the first portion.

10. The display device of claim 1, wherein the plurality of subpixels include a first subpixel emitting red, a second subpixel emitting green, and a third subpixel emitting blue,
wherein horizontal widths of the first portions of the second planarization layer included in each of the first subpixel, the second subpixel and the third subpixel are different from each other.

11. A display device, comprising:
a substrate on which a plurality of subpixels is disposed, each of the plurality of subpixels including a light emitting area;
a first planarization layer on the substrate; and
a second planarization layer which is disposed on the first planarization layer, and comprises at least a part of a convex portion located in an area overlapping at least a part of the light emitting area and having a convex upper surface in a direction opposite of the first planarization layer.

12. The display device of claim 11, further comprising a first electrode disposed on the second planarization layer,
wherein the first electrode has a convex shape on the convex portion.

13. The display device of claim 12, further comprising a light emitting layer disposed on the first electrode,
wherein the light emitting layer has a convex shape in an area overlapping with the convex portion.

14. The display device of claim 11, wherein a thickness of the convex portion is greatest at a center of the convex portion.

15. The display device of claim 11, wherein a thickness of the convex portion gradually increases from an edge area of the convex portion to a center of the convex portion.

16. The display device of claim 11, wherein the plurality of subpixels include a first subpixel emitting red, a second subpixel emitting green, and a third subpixel emitting blue,
wherein horizontal widths of the convex portions of the second planarization layer included in each of the first subpixel, the second subpixel and the third subpixel are different from each other.

17. The display device of claim 11, wherein the first planarization layer and the second planarization layer are separate and distinct from each other.

18. A display device, comprising:
a substrate on which a plurality of subpixels is disposed, each of the plurality of subpixels including a light emitting element; and
a planarization layer on the substrate, the planarization layer having a first portion and a second portion adjacent to the first portion,
wherein the first portion of the planarization layer includes a first surface, and
wherein the first surface of the first portion is curved such that a thickness of the first portion of the planarization layer is thickest at the center of the first portion of the planarization layer.

19. The display device of claim 18, wherein the light emitting element includes a first electrode, a second electrode, and a light emitting layer between the first and second electrodes,
wherein the light emitting layer overlaps with the first surface of the first portion of the planarization layer from a plan view.

20. The display device of claim 18, wherein the second portion of the planarization layer includes a second surface,
wherein the light emitting element includes a first electrode, a second electrode, and a light emitting layer between the first and second electrodes, and
wherein the first electrode is continuously and contiguously disposed on the second surface of the second portion of the planarization layer and the first surface of the first portion of the planarization layer.

21. The display device of claim 20, wherein the light emitting layer is spaced apart from the second surface of the second portion of the planarization layer.

22. The display device of claim 21, comprising a bank layer between the light emitting layer and the second surface of the second portion of the planarization layer.

23. The display device of claim 20, wherein the second portion of the planarization layer includes a step having a first height.

24. The display device of claim 23, wherein the first height of the step is greater than a height of thickest portion at the center of the first portion of the planarization layer.

25. The display device of claim 20, wherein the display device includes a first light emitting area, a first non-emission area, and a second light emitting area from a plan view,
wherein the first light emitting area overlaps with the light emitting layer from a plan view,
wherein the second light emitting area overlaps with the second surface of the second portion of the planarization layer from a plan view, and
wherein the first non-emission area is disposed between the first light emitting area and the second light emitting area from a plan view.

26. The display device of claim 25, wherein the first non-emission area surrounds the first light emitting area, and the second light emitting area surrounds the first non-emission area from a plan view.
